(19) United States
(12) Patent Application Publication
(10) Pub. No.: US 2015/0340324 A1
(43) Pub. Date: Nov. 26, 2015

(54) Integrated Circuit Die And Package

(71) Applicant: Texas Instruments Incorporated, Dallas, TX (US)

(72) Inventors: Kazunori Hayata, Minami-Alps City (JP); Yohei Koto, Yokohama City (JP); Dan Okamoto, Oita (JP)

(73) Assignee: Texas Instruments Incorporated, Dallas, TX (US)

(21) Appl. No.: 14/284,644

(22) Filed: May 22, 2014

(51) Int. Cl. H01L 23/544; H01L 23/31; H01L 21/78

(52) U.S. Cl. CPC H01L 23/544; H01L 21/78; H01L 23/3178

(57) ABSTRACT

A semiconductor package assembly includes a substrate having an upper surface with a die attachment region thereon. A layer of die attachment material is positioned on top of the die attachment region. The semiconductor package assembly also includes an integrated circuit (“IC”) die. The die has a top portion including a laterally extending top wall surface and a plurality of generally vertically extending wall surfaces extending downwardly from the top wall surface. The die has a metallized bottom portion. The bottom portion has at least two metallized laterally extending wall surfaces and a plurality of metallized generally vertically extending connecting surfaces that connect the metallized laterally extending surfaces of the bottom portion. The layer of die attachment material interfaces with one or both of the metallized laterally extending surfaces and the plurality of metallized generally vertically extending connecting wall surfaces.

### BACKGROUND

Integrated circuits, also referred to as “IC's” or “semiconductor chips” or simply “chips,” are electronic circuits made by diffusion of trace elements into the surface of thin substrates of semiconductor material. Integrated circuits were first produced in the mid 20^{th} Century. Because of their small size and relatively low production cost, integrated circuits are now used in most modern electronics. Semiconductor chips are typically mass produced in the form of a single wafer that contains a large number of identical integrated circuits. The wafer is cut (“singulated”) into a number of individual semiconductor chips referred to as “dies” or “dice.”

Dies are “packaged” to prevent damage to the dies and to facilitate attachment of the dies to circuit boards. Various packaging materials and processes have been used to package integrated circuit dies. One conventional packaging method involves mounting individual dies in a predetermined pattern on a substrate strip. The strip mounted dies are encapsulated in a plastic material, such as by a transfer molding process.

The encapsulated dies are singulated into individual integrated circuit packages by cutting the encapsulated die/substrate strip in accordance with the predetermined die mounting pattern. Typical cutting tools include lasers, saws and punches. Each integrated circuit package generally includes at least one die and the underlying portion of the substrate strip on which it was mounted. The underlying portion of the substrate strip is sometimes a lead frame to which the die is electrically connected. The inactive side (“backside”) of the die is generally attached to a centrally positioned die attachment pad on the leadframe. Some dies have an electrically conductive backside and are attached to the die attachment pad by a conductive medium such as solder or a conductive adhesive.

The active side (front side) of the die usually includes a number of electrical contact pads that are attached to lead fingers of the leadframe and/or directly to other electronic devices. A typical connection method is wire bonding in which a thin gold, copper or aluminum wire is welded to the die pad at one end and to a lead finger or another electronic device at the other end.

### BRIEF DESCRIPTION OF THE DRAWINGS

FIG. 1 is a side elevation view of a prior art integrated circuit (IC) die attached to a substrate of an IC package.

FIG. 2 is a plan view of the backside of an integrated circuit wafer.

FIG. 3 is a cross-sectional side elevation view of a portion of the wafer of FIG. 2.

FIG. 4 is a cross-sectional sign elevation view of the wafer portion of FIG. 3 after surface metallization.

FIG. 5 is a cross-sectional sign elevation view of the metallized wafer portion of FIG. 4 after singulation (dicing) thereof into a plurality of dies.

FIG. 6 is a side elevation view of one of the metallized dies of FIG. 5 attached to a substrate of an IC package.

FIG. 7 is a bottom isometric view of one of the metallized dies of FIG. 5.

FIG. 8 is a top plan view of the metallized die of FIG. 7.

FIG. 9 is a flowchart of one embodiment of a method of making an integrated circuit (“IC”) package.

FIG. 10 is a flowchart of another embodiment of a method of making an integrated circuit (“IC”) package.

### DETAILED DESCRIPTION

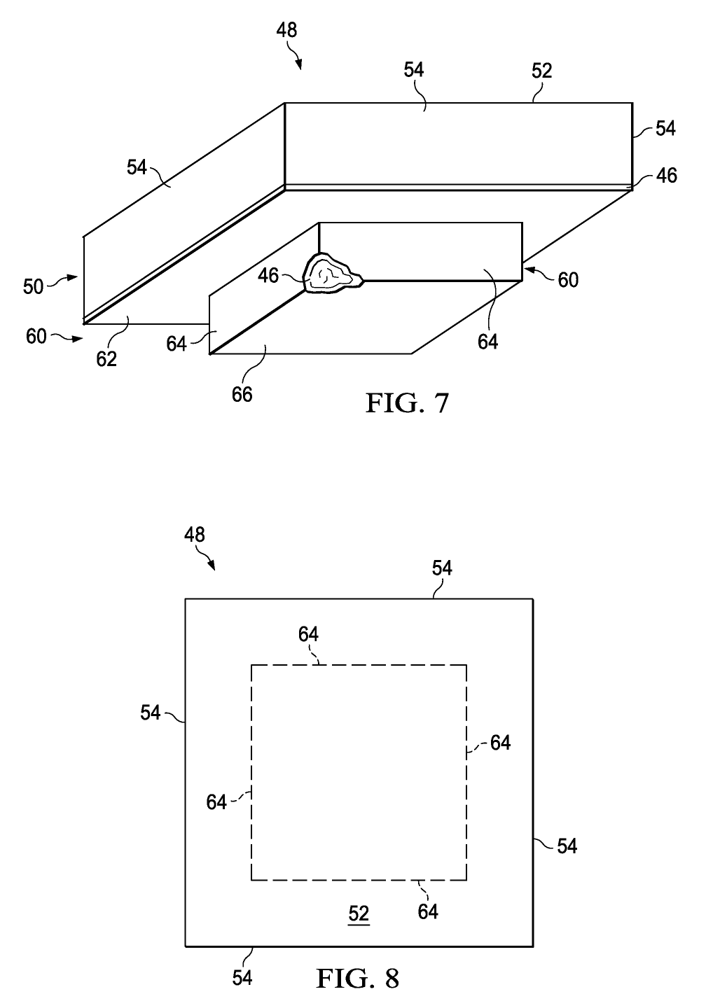

This specification, in general, discloses a semiconductor package assembly 80, FIG. 6. The assembly 80 includes a substrate 70 having a top surface 76 with a die attachment region 74 thereon. A layer of die attachment material 72 is positioned on top of the die attachment region 74. The semiconductor package assembly 80 also includes an integrated circuit (“IC”) die 48. The die 48 has a top portion 50 including a laterally extending top wall surface 52 and a plurality of generally vertical wall surfaces 54 extending downwardly from the top wall surface 52, as best shown in FIG. 7. The die 48 has a metallized bottom portion 60, i.e., the entire bottom portion is covered by a metallization layer 46. The bottom portion is connected to the plurality of generally vertical wall surfaces 54 in the top portion 50. A plurality of connecting wall surfaces, which may be vertical wall surfaces 64, 64, etc, connect the laterally extending wall surfaces 62, 66 of the bottom portion 60. The layer of die attachment material 72 interfaces with at least one of the laterally extending lower surfaces 62, 66 and the plurality of connecting wall surfaces 64, 64, etc.

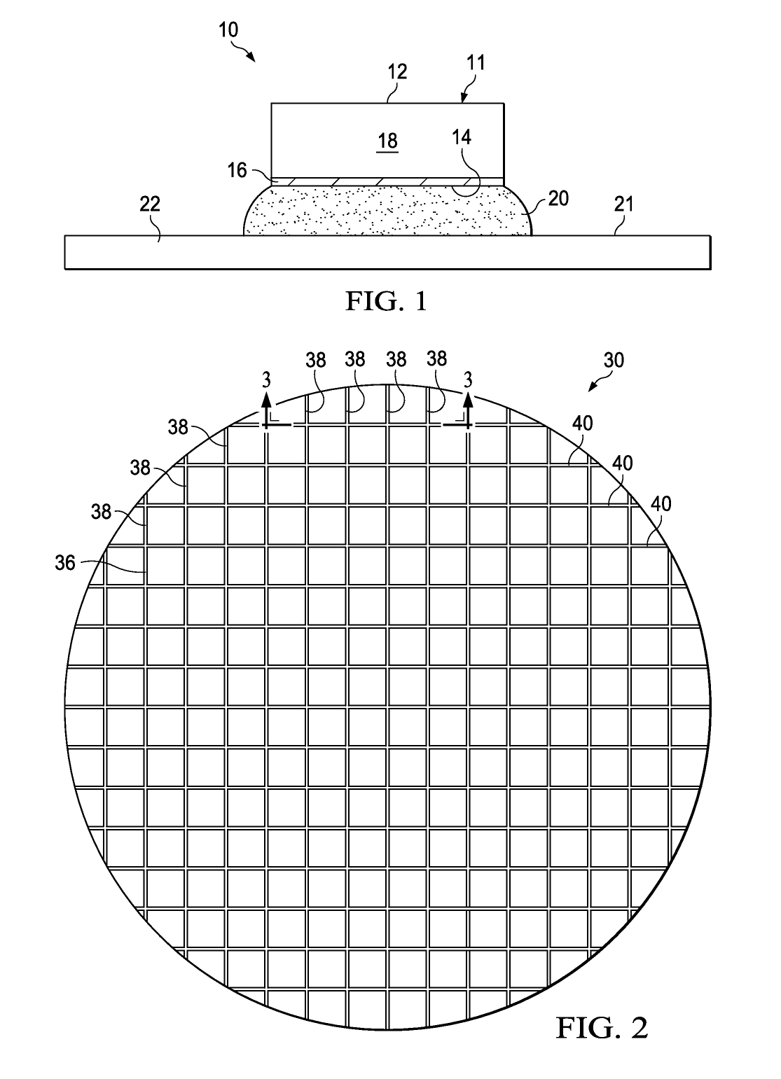

FIG. 1 illustrates a prior art integrated circuit package assembly 10. The assembly includes an IC die 11 with a top, active surface 12. The active surface 12 has conventional contact pads and the like provided thereon for connecting the die 11 to other circuit devices (not shown). The die has a flat bottom surface 14 and a plurality of vertically extending side surfaces 18. A metallization layer 16 covers the flat bottom surface 14. The metallized bottom surface 14 interfaces with an adhesive layer 20 that is applied to a top surface 21 of a substrate 22. The bond between the metallized bottom surface 14 and the adhesive layer 20 is sometimes not sufficiently strong to firmly attach the die 11 to the substrate 22.

A new die configuration is described below. This new die configuration is designed to provide a stronger bond between a die and substrate than the prior art structure described in the preceding paragraph.

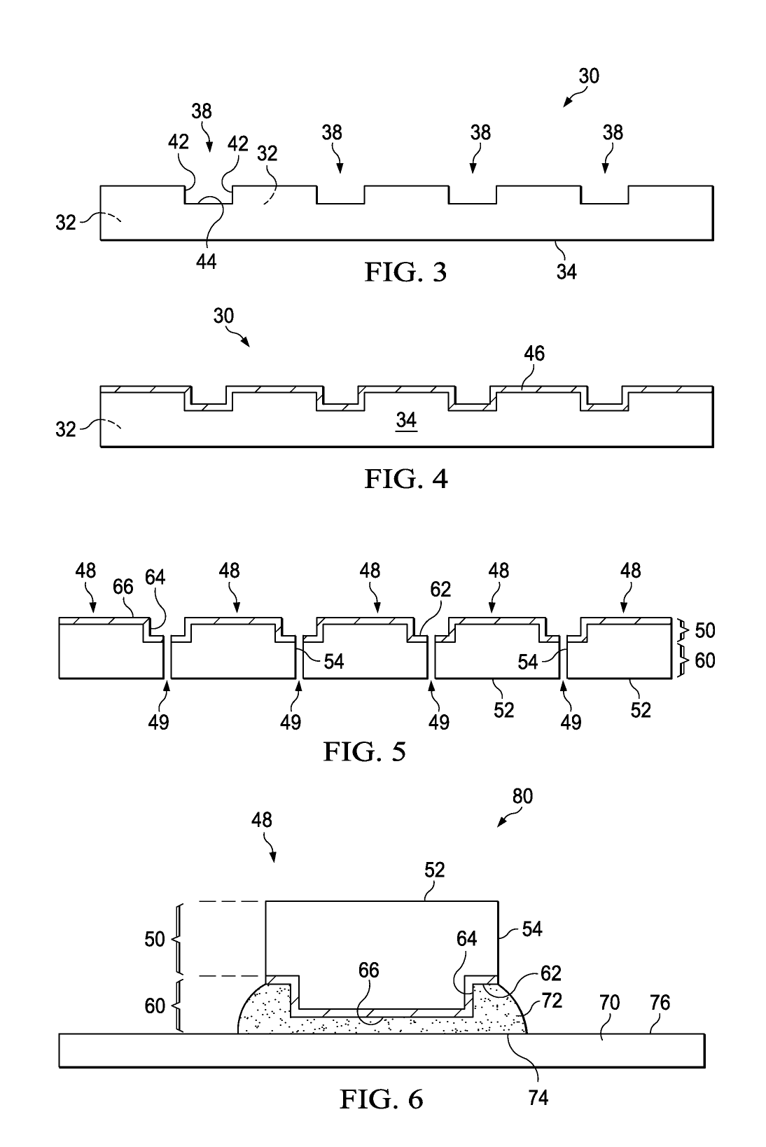

FIG. 2 is a bottom plan view of an integrated circuit wafer 30, and FIG. 3 is a cross-sectional elevation view of a portion of the wafer 30. The IC wafer 30 has an inactive backside 32 and an active front side 34. The backside 32 has a gridwork of intersecting grooves 36 formed thereon. The gridwork of grooves 36 includes a plurality of parallel grooves 38 extending a first direction and a plurality of parallel grooves 40 extending in a second direction, which may be generally perpendicular to the first direction. The grooves 36 may be formed by conventional means such as by grooving saw blades or stealth laser. Each groove, e.g. 38 may comprises a pair of oppose vertical surfaces 42 connected by a flat lateral surface 44, as shown in FIG. 3. In one example embodiment, each groove has a width of about 20-50 um and a depth of about half the wafer thickness.

Next, the backside surface 32 of the wafer 30, including all groove surfaces 42, 42, 44, is metallized. FIG. 4 is a cross-sectional view of the wafer portion of FIG. 3, after metallization of the entire backside surface 32. Metallization of a wafer with a flat backside surface is known the art. Backside metallization of a grooved wafer 30 is new, so far as applicants are aware. In one embodiment metallization is performed using sputtering, vacuum deposition and electroless plating. The metallization thickness/depth may be in a range of about 1 to 5 um.

Next, as illustrated in FIG. 5, the wafer 30 is diced (singulated). The singulation cuts 49 may be performed by a punch, a conventional singulation saw a stealth laser or other techniques now known in the art or later developed. The cuts 49 may be made at the centerline of each groove 38. The width of a typical cut 49 may be about 10-40 um. The cuts 49 produce a plurality of dies 48, In use, the dies 48 are flipped over into the orientation shown in FIGS. 7 and 8. FIG. 7 is a bottom isometric view of a die 48, and FIG. 8 is a top plan view of the die. (The orientation of the die 48 that is shown in FIGS. 7 and 8 is used for descriptive purposes to provide a frame of reference for associated terminology, such as “up,” “down,” “vertical” “lateral,” etc. It will be understood that these terms are used in a relative sense with respect to the illustrated orientation, i.e., they are not used to denote an absolute orientation of the die with respect to a field of gravity. Rather, these terms are used to denote the relative positions of various structure and surfaces of the die 48 regardless of the orientation of the die relative to the earth.)

As best shown in FIGS. 6, 7 and 8, each die 48 has an uncoated top portion 50 and a metalized bottom portion 60. The top portion 50 includes a rectangular front (active) wall surface 52 corresponding to the active wall surface 34 of the substrate. It also includes four identical vertical wall surfaces 54 formed by singulation. The bottom portion 60 includes a first metallized laterally extending wall surface 62, corresponding to groove bottom surfaces 44 after application of the coating layer 46 thereto. Metallized lateral wall surface 62 is connected to the four uncoated vertical wall surfaces 54 of the top portion 50. The bottom portion 60 also includes a second (bottom most) metallized, laterally extending wall surface 66, which is the metallized backside surface of the die 48, and which corresponds to wafer backside surface 32. The two laterally extending surfaces 62, 66 are connected by four metalized vertically extending connecting surfaces 64. Surfaces 64 correspond to groove vertical surfaces 42 shown in FIG. 3, after application of metallization layer 46.

As illustrated in FIG. 6, a layer of die attachment material 72, such as solder paste or conductive adhesive, is applied to a die attach region 74 of the substrate 70. A die 48 is then placed in interfacing relationship with the attachment material 72, such that the two laterally extending wall surfaces 62, 66 and the vertically extending wall surfaces 64 in the bottom portion 60 of the die 48 interface with the attachment material 72. In another embodiment (not shown) the attachment material only interfaces with the bottom metallized wall surface 66 and the vertical metallized wall surfaces 64.

Next the attachment material 72 is cured, such as by placing the substrate 70 in a reflow furnace when the attachment material is solder or a curing oven when it is conductive adhesive. In the illustrated embodiment the attachment material 72 firmly bonds with all of the lateral and vertical metallized wall surfaces 62, 64, 66 on the die bottom portion 60. The total amount of bonding area on the two lateral wall surfaces 62, 64 is about the same amount as in a conventional die attach process, such as shown in FIG. 1, when a single large backside surface is bonded. However, nothing corresponding to the bonding that takes place on the four vertical wall surfaces 64 takes place in the prior art die attachment method. As a result, with the new die attachment method a substantial additional displacement force can be resisted. Accordingly, a significantly more robust circuit package 80 is provided. Also, even if full contact is not made with the lateral surface 62, the additional contact with the four vertical surfaces 64 may still produce more resistance to separation forces than the prior art structure.

Next the package may be completed by conventional techniques, such as by connecting other components (not shown) and covering the die 48, other components and substrate 70 with mold compound (not shown). In some cases the mold compound (not shown) encased die 48, other components and substrate 70 are singulated from other identical assemblies mounted on a substrate strip. In one embodiment the die 48 and substrate 70 are components of a power IC package 80.

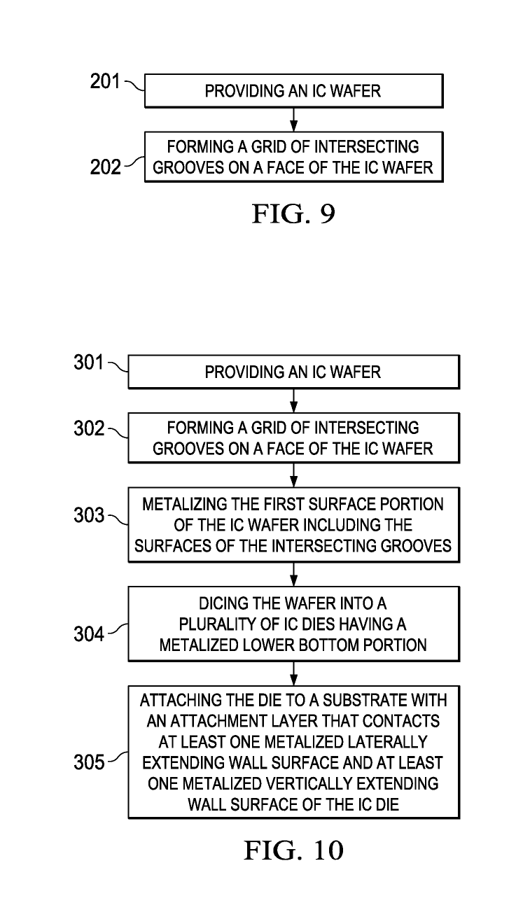

FIG. 9 illustrates one embodiment of a method of making an integrated circuit (“IC”) package. This method embodiment includes, as shown at block 201, providing an IC wafer and, as shown at block 202, forming a grid of intersecting grooves on a face of the IC wafer.

FIG. 10 illustrates another embodiment of a method of making an integrated circuit (“IC”) package. This method embodiment includes as shown at block 301, providing an IC wafer and, as shown at block 302, forming a grid of intersecting grooves on a face of the IC wafer. The method further includes as shown at blocks 303 metalizing the first surface portion of the IC wafer including the surfaces of the intersecting grooves and, as shown at block 304 dicing the wafer into a plurality of IC dies having a metalized lower bottom portion. The method also includes, as shown at block 305, attaching the die to a substrate with an attachment layer that contacts at least one metalized laterally extending wall surface and at least one metalized vertically extending wall surface of the IC die.

Certain specific embodiments of an IC package, an IC die and a method of making an IC package have been described in detail herein. Other embodiments will occur to those skilled in the art after reading this disclosure. It is intended that the appended claims be broadly construed to cover all such alternative embodiments, except to the extent limited by the prior art.

1. A semiconductor package assembly comprising:
a substrate having an upper surface with a die attachment area thereon;
a layer of die attachment material on top of said die attachment area;
an integrated circuit (“IC”) die having:
a laterally extending top wall surface;
a plurality of generally vertically extending wall surfaces extending downwardly from said top wall surface;
a metallized bottom portion connected to said plurality of generally vertically extending wall surfaces, said metallized bottom portion comprising at least two laterally extending metallized wall surfaces and at least one metallized connecting wall surface connecting said at least two laterally extending metallized wall surfaces;
said layer of die attachment material interfacing with at least one of said at least two laterally extending metallized wall surface and said at least one metallized connecting wall surface.

2. The semiconductor package of claim 1, said layer of die attachment material interfacing with more than one of said at least two laterally extending metallized wall surfaces and said at least one metallized connecting wall surface.

3. The semiconductor package of claim 1, wherein said at least one metallized connecting wall surface is positioned laterally inwardly of said plurality of generally vertically extending wall surfaces.

4. The semiconductor package of claim 1 wherein said IC die has an inverted double pedestal shape.

5. The semiconductor of claim 4 wherein said inverted double pedestal shape has identically shaped front, back and opposite side portions.

6. An integrated circuit (“IC”) die comprising a bottom portion having at least two laterally extending wall surfaces and at least one metallized connecting wall surface connecting said at least two laterally extending wall surfaces.

7. The IC die of claim 6 wherein said at least one metallized connecting wall surface comprises four metallized vertical connecting wall surfaces.

8. The IC die of claim 6 wherein said bottom portion has two metallized laterally extending wall surfaces and four metallized vertically extending connecting wall surfaces.

9. The IC die of claim 6, said bottom portion having a surface that is entirely metallized

10. A method of making an integrated circuit (“IC”) package comprising:
providing an IC wafer; and
forming a grid of intersecting grooves on a back side of said IC wafer.

11. The method of claim 10 further comprising metalizing the grooved back side of the IC wafer.

12. The method of claim 11 further comprises dicing the wafer into a plurality of IC dies each having a metalized backside portion.

13. The method of claim 12 wherein said dicing comprises forming cuts in the wafer positioned inside the intersecting grooves.

14. The method of claim 13 wherein forming cuts comprises forming cuts that are centered in the grooves.

15. The method of claim 10 wherein forming a grid of intersecting grooves comprises forming grooves that have depths of about half the thickness of the wafer.

16. The method of claim 12 further comprising:
providing a substrate;
attaching the die to the substrate with an adhesive layer that contacts at least one metalized vertically extending wall surface of the IC die.

17. The method of claim 16 wherein attaching the die to the substrate with an adhesive layer that contacts at least one metalized vertically extending wall surface of the IC die comprises attaching the die to the substrate with an attachment layer that contacts at least one metalized vertically extending wall surface and at least one metalized laterally extending wall surface of the IC die.

18. The method of 13 wherein forming cuts comprises forming cuts that have a width less than the width of the grooves and that are centered in the grooves and that have a depth of about half the thickness of the wafer.

19. The method of claim 17 wherein attaching the die to the substrate with an attachment layer comprises attaching the die to the substrate with an attachment layer that comprises at least one of solder and conductive adhesive paste.

20. The method of claim 10 wherein making an (“IC”) package comprised making a power IC package.
